(19) United States
(12) Patent Application Publication
(10) Pub. No.: US 2025/0246435 A1
(43) Pub. Date: Jul. 31, 2025

(54) CRYOGENIC ETCHING OF SILICON-CONTAINING MATERIALS

(71) Applicant: Applied Materials, Inc., Santa Clara, CA (US)

(72) Inventors: Lei Liao, San Jose, CA (US); Qian Fu, Pleasanton, CA (US); Sumit Agarwal, Dublin, CA (US); Yeonju Kwak, Sunnyvale, CA (US); Daisuke Shimizu, Milpitas, CA (US)

(73) Assignee: Applied Materials, Inc., Santa Clara, CA (US)

(21) Appl. No.: 18/671,417

(22) Filed: May 22, 2024

Related U.S. Application Data
(60) Provisional application No. 63/627,716, filed on Jan. 31, 2024.

(51) Int. Cl. H01L 21/311; H01L 21/3213

(52) U.S. Cl. CPC H01L 21/31116; H01L 21/31144; H01L 21/32137; H01L 21/32139

(57) ABSTRACT

Exemplary semiconductor processing methods may include providing an etchant precursor to a processing region of a semiconductor processing chamber. A substrate may be disposed within the processing region. The substrate may include a layer of a silicon-containing material. The silicon-containing material may be a silicon-and-carbon-containing material, a silicon-carbon-and-nitrogen-containing material, a silicon-and-nitrogen-containing material, a silicon-and-oxygen-containing material, or silicon material. The methods may include forming plasma effluents of the etchant precursor. The methods may include contacting the substrate with the plasma effluents of the etchant precursor. The contacting may etch a portion of the layer of the silicon-containing material. The processing region may be maintained at a cryogenic temperature while contacting the substrate with the plasma effluents of the etchant precursor.

### CROSS-REFERENCE TO RELATED APPLICATIONS

This application claims the benefit of and priority to U.S. Provisional Application No. 63/627,716, filed Jan. 31, 2024, which is hereby incorporated by reference in its entirety for all purposes.

### TECHNICAL FIELD

The present technology relates to semiconductor processes and equipment. More specifically, the present technology relates to cryogenic etching of silicon-containing materials.

### BACKGROUND

Integrated circuits are made possible by processes which produce intricately patterned material layers on substrate surfaces. Producing patterned material on a substrate requires controlled methods for removal of exposed material. Chemical etching is used for a variety of purposes including transferring a pattern in photoresist into underlying layers, thinning layers, or thinning lateral dimensions of features already present on the surface. Often it is desirable to have an etch process that etches one material faster than another facilitating, for example, a pattern transfer process. Such an etch process is said to be selective to the first material. As a result of the diversity of materials, circuits, and processes, etch processes have been developed with a selectivity towards a variety of materials.

Etch processes may be termed wet or dry based on the materials used in the process. A wet HF etch preferentially removes silicon oxide over other dielectrics and materials. However, wet processes may have difficulty penetrating some constrained trenches and also may sometimes deform the remaining material. Dry etches produced in local plasmas formed within the substrate processing region can penetrate more constrained trenches and exhibit less deformation of delicate remaining structures. However, local plasmas may damage the substrate through the production of electric arcs as they discharge.

Thus, there is a need for improved systems and methods that can be used to produce high quality devices and structures. These and other needs are addressed by the present technology.

### SUMMARY

Exemplary semiconductor processing methods may include providing an etchant precursor to a processing region of a semiconductor processing chamber. A substrate may be disposed within the processing region. The substrate may include a layer of a silicon-containing material. The silicon-containing material may be a silicon-and-carbon-containing material, a silicon-carbon-and-nitrogen-containing material, a silicon-and-nitrogen-containing material, a silicon-and-oxygen-containing material, or silicon material. The methods may include forming plasma effluents of the etchant precursor. The methods may include contacting the substrate with the plasma effluents of the etchant precursor. The contacting may etch a portion of the layer of the silicon-containing material. The processing region may be maintained at a cryogenic temperature while contacting the substrate with the plasma effluents of the etchant precursor.

In some embodiments, the substrate may further include a patterned mask material overlying the layer of the silicon-containing material. The silicon-containing material may be or include a silicon-and-nitrogen-containing material, and the etchant precursor may be or include hydrogen fluoride (HF), nitrogen trifluoride (NF₃), sulfur hexafluoride (SF₆), or a fluorocarbon (CHₓF_{y}). The silicon-containing material may be or include a silicon-and-oxygen-containing material, and the etchant precursor may be or include hydrogen fluoride (HF), nitrogen trifluoride (NF₃), or a fluorocarbon (CHₓF_{y}). The methods may include providing a carbon-containing precursor to the processing region with the etchant precursor. The plasma effluents of the etchant precursor may be an inductively coupled plasma (ICP). The methods may include applying a bias power while contacting the substrate with the plasma effluents of the etchant precursor.

Some embodiments of the present technology may encompass semiconductor processing methods. The methods may include providing a first etchant precursor to a processing region of a semiconductor processing chamber. A substrate may be disposed within the processing region. The substrate may include a layer of a first silicon-containing material and a layer of a second silicon-containing material. The first silicon-containing material and the second silicon-containing material may be a silicon-and-carbon-containing material, a silicon-carbon-and-nitrogen-containing material, a silicon-and-nitrogen-containing material, a silicon-and-oxygen-containing material, or silicon material. The first silicon-containing material and the second silicon-containing material may be different silicon-containing materials. The methods may include forming plasma effluents of the first etchant precursor. The methods may include contacting the substrate with the plasma effluents of the first etchant precursor at a cryogenic temperature. The contacting may etch a portion of the layer of the first silicon-containing material. The methods may include providing a second etchant precursor to the processing region. The methods may include forming plasma effluents of the second etchant precursor. The methods may include contacting the substrate with the plasma effluents of the second etchant precursor at a cryogenic temperature. The contacting may etch a portion of the layer of the second silicon-containing material. The processing region may be maintained at a cryogenic temperature.

In some embodiments, the first etchant precursor and the second etchant precursor may be or include hydrogen fluoride (HF), nitrogen trifluoride (NF₃), fluoromethane (CH₃F), carbon tetrafluoride (CF₄), fluoroform (CHF₃), difluoromethane (CH₂F₂), hexafluorobutadiene (C₄F₆), or sulfur hexafluoride (SF₆). The methods may include halting a flow of the first etchant precursor prior to providing the second etchant precursor. The methods may include providing a carbon-containing precursor with the first etchant precursor, the second etchant precursor, or both. The methods may include passivating a sidewall of the portion of the layer of the first silicon-containing material, a sidewall of the portion of the layer of the second silicon-containing material, or both. The portion of the layer of the first silicon-containing material, the portion of the layer of the second silicon-containing material, or both may be characterized by a critical dimension of greater than or about 100 nm. The substrate may further include a layer of a metal-and-nitrogen-containing material on the layer of the first silicon-containing material. The substrate may further include a patterned mask material on the layer of the metal-and-nitrogen-containing material. The layer of the first silicon-containing material may be or include silicon-and-oxygen-containing material. The layer of the second silicon-containing material may be or include silicon material. The processing region may be maintained at a pressure of less than or about 500 mTorr.

Some embodiments of the present technology may encompass semiconductor processing methods. The methods may include providing a first etchant precursor to a processing region of a semiconductor processing chamber. A substrate may be disposed within the processing region. The substrate may include a layer of a first silicon-containing material, a layer of a second silicon-containing material, and a layer of a third silicon-containing material. The first silicon-containing material, the second silicon-containing material, and the second silicon-containing material may be or include a silicon-and-carbon-containing material, a silicon-carbon-and-nitrogen-containing material, a silicon-and-nitrogen-containing material, a silicon-and-oxygen-containing material, or silicon material. The first silicon-containing material, the second silicon-containing material, and the second silicon-containing material may be different silicon-containing materials. The methods may include forming plasma effluents of the first etchant precursor. The methods may include contacting the substrate with the plasma effluents of the first etchant precursor at a cryogenic temperature. The contacting may etch a portion of the layer of the first silicon-containing material. The methods may include providing a second etchant precursor to the processing region. The methods may include forming plasma effluents of the second etchant precursor. The methods may include contacting the substrate with the plasma effluents of the second etchant precursor at a cryogenic temperature. The contacting may etch a portion of the layer of the second silicon-containing material. The methods may include providing a third etchant precursor to the processing region. The methods may include forming plasma effluents of the third etchant precursor. The methods may include contacting the substrate with the plasma effluents of the third etchant precursor at a cryogenic temperature. The contacting may etch a portion of the layer of the third silicon-containing material.

In some embodiments, the methods may include applying a bias power contacting the substrate with the plasma effluents of the first etchant precursor, the plasma effluents of the second etchant precursor, and the plasma effluents of the third etchant precursor. Contacting the substrate with the plasma effluents of the first etchant precursor, the plasma effluents of the second etchant precursor, and the plasma effluents of the third etchant precursor may be performed in the same semiconductor processing chamber.

Such technology may provide numerous benefits over conventional systems and techniques. For example, the processes may etch stacked layers including multiple layers of silicon-containing materials within semiconductor structures. Additionally, the processes may etch materials at cryogenic temperatures to increase etch rates and etch uniformity. Further, the processes may etch multiple silicon-containing materials in a single chamber using different etchant precursors. These and other embodiments, along with many of their advantages and features, are described in more detail in conjunction with the below description and attached figures.

### BRIEF DESCRIPTION OF THE DRA WINGS

A further understanding of the nature and advantages of the disclosed technology may be realized by reference to the remaining portions of the specification and the drawings.

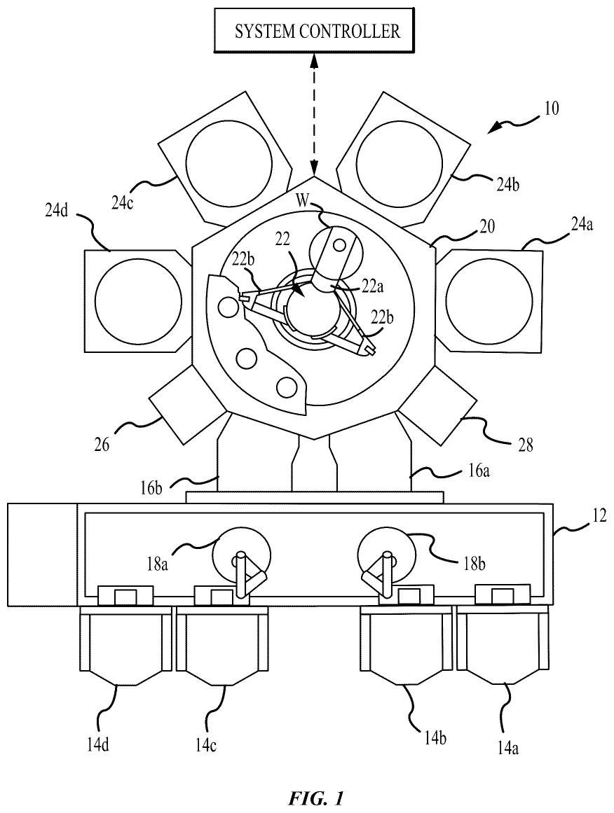

FIG. 1 shows a top plan view of one embodiment of an exemplary processing system according to some embodiments of the present technology.

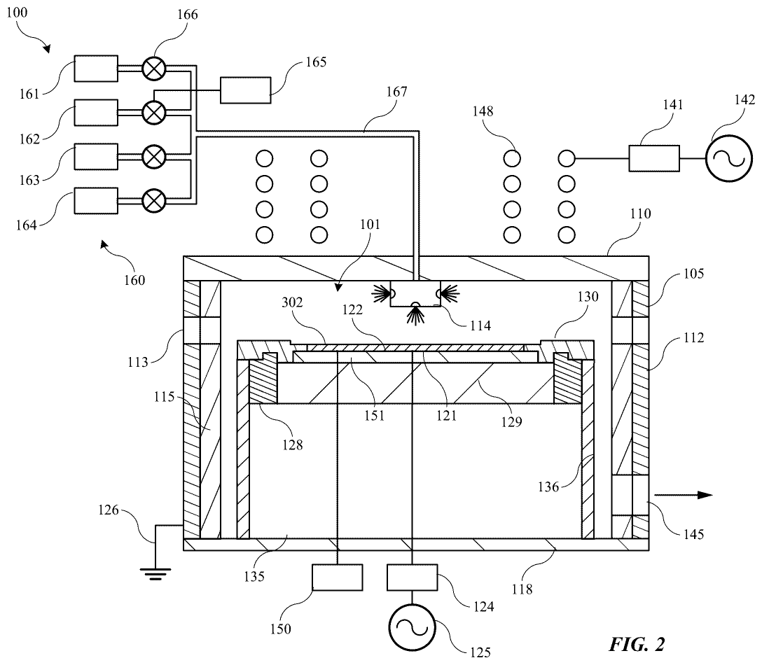

FIG. 2 shows a schematic cross-sectional view of an exemplary processing chamber according to some embodiments of the present technology.

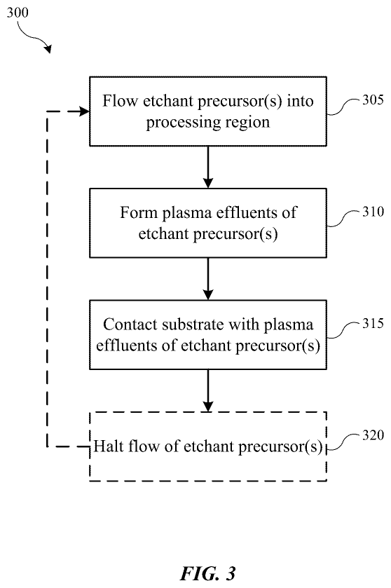

FIG. 3 shows exemplary operations in a method according to some embodiments of the present technology.

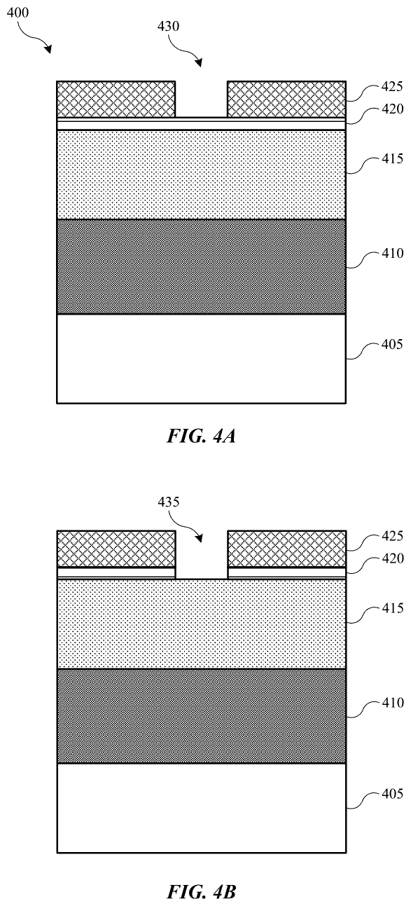

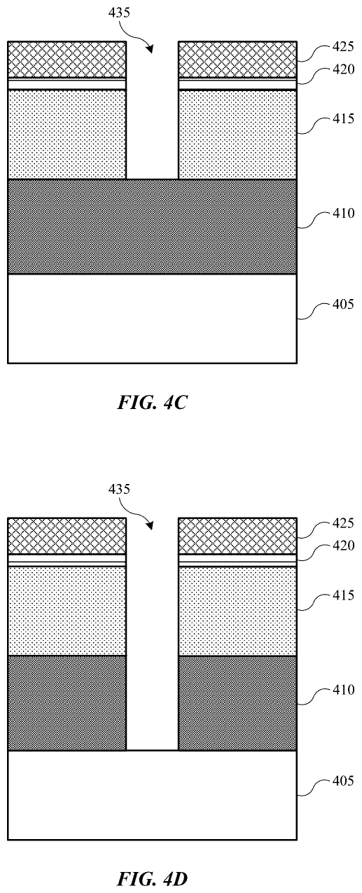

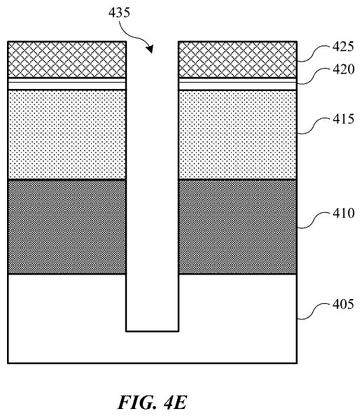

FIGS. 4A-4E show cross-sectional views of substrates being processed according to some embodiments of the present technology.

Several of the figures are included as schematics. It is to be understood that the figures are for illustrative purposes, and are not to be considered of scale unless specifically stated to be of scale. Additionally, as schematics, the figures are provided to aid comprehension and may not include all aspects or information compared to realistic representations, and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

In transitioning from 2D devices to 3D devices, many process operations are modified from horizontal to vertical operations. Additionally, as 3D structures grow in the number of transistors being formed, the aspect ratios of layers and other features increase, sometimes dramatically. During 3D device processing, one or more holes or trenches may be etched into the stacks of layers on the substrate.

Many conventional technologies utilize Bosch processes for etching holes or trenches characterized by high aspect ratios into layers of materials, such as silicon-containing materials. For example, numerous loops of passivation deposition and etching are repeatedly performed to etch a hole or trench into a material, such as a silicon-containing material. Additionally, when multiple different layers, such as multiple layers of different silicon-containing materials are present and to be etched through, multiple semiconductor processing chambers may be needed to perform the etching. Furthermore, the repeated passivation deposition and etching may result in a sidewall of the hole or trench with increased surface roughness.

The present technology overcomes these issues by performing an etch process at cryogenic temperatures using etchant precursors and optional passivation precursors, such as carbon-containing precursors and/or sulfur-containing precursors, to etch uniform features into multiple layers of material, such as silicon-containing materials. By using specific precursors and performing the etching at cryogenic temperatures, the processes of the present technology may etch through various layers of material, such as multiple silicon-containing materials, without performing intermittent passivation deposition operations. Thus, the present technology may successfully etch through layers of material, such as multiple silicon-containing materials, efficiently in a single semiconductor processing chamber and with reduced surface roughness of a sidewall of the hole or trench being etched.

Although the remaining disclosure will routinely identify specific etching processes utilizing the disclosed technology, it will be readily understood that the systems and methods are equally applicable to deposition and cleaning processes as may occur in the described chambers. Accordingly, the technology should not be considered to be so limited as for use with etching processes or chambers alone. Moreover, although an exemplary chamber is described to provide foundation for the present technology, it is to be understood that the present technology can be applied to virtually any semiconductor processing chamber that may allow the single-chamber operations described.

FIG. 1 shows a top plan view of one embodiment of a processing system 10 of deposition, etching, baking, and/or curing chambers according to embodiments. The tool or processing system 10 depicted in FIG. 1 may contain a plurality of process chambers, 24a-d, a transfer chamber 20, a service chamber 26, an integrated metrology chamber 28, and a pair of load lock chambers 16a-b. The process chambers may include any number of structures or components, as well as any number or combination of processing chambers.

To transport substrates among the chambers, the transfer chamber 20 may contain a robotic transport mechanism 22. The transport mechanism 22 may have a pair of substrate transport blades 22a attached to the distal ends of extendible arms 22b, respectively. The blades 22a may be used for carrying individual substrates to and from the process chambers. In operation, one of the substrate transport blades such as blade 22a of the transport mechanism 22 may retrieve a substrate W from one of the load lock chambers such as chambers 16a-b and carry substrate W to a first stage of processing, for example, a treatment process as described below in chambers 24a-d. The chambers may be included to perform individual or combined operations of the described technology. For example, while one or more chambers may be configured to perform a deposition or etching operation, one or more other chambers may be configured to perform a pre-treatment operation and/or one or more post-treatment operations described. Any number of configurations are encompassed by the present technology, which may also perform any number of additional fabrication operations typically performed in semiconductor processing.

If the chamber is occupied, the robot may wait until the processing is complete and then remove the processed substrate from the chamber with one blade 22a and may insert a new substrate with a second blade. Once the substrate is processed, it may then be moved to a second stage of processing. For each move, the transport mechanism 22 generally may have one blade carrying a substrate and one blade empty to execute a substrate exchange. The transport mechanism 22 may wait at each chamber until an exchange can be accomplished.

Once processing is complete within the process chambers, the transport mechanism 22 may move the substrate W from the last process chamber and transport the substrate W to a cassette within the load lock chambers 16a-b. From the load lock chambers 16a-b, the substrate may move into a factory interface 12. The factory interface 12 generally may operate to transfer substrates between pod loaders 14a-d in an atmospheric pressure clean environment and the load lock chambers 16a-b. The clean environment in factory interface 12 may be generally provided through air filtration processes, such as HEPA filtration, for example. Factory interface 12 may also include a substrate orienter/aligner that may be used to properly align the substrates prior to processing. At least one substrate robot, such as robots 18a-b, may be positioned in factory interface 12 to transport substrates between various positions/locations within factory interface 12 and to other locations in communication therewith. Robots 18a-b may be configured to travel along a track system within factory interface 12 from a first end to a second end of the factory interface 12.

The processing system 10 may further include an integrated metrology chamber 28 to provide control signals, which may provide adaptive control over any of the processes being performed in the processing chambers. The integrated metrology chamber 28 may include any of a variety of metrological devices to measure various film properties, such as thickness, roughness, composition, and the metrology devices may further be capable of characterizing grating parameters such as critical dimensions, sidewall angle, and feature height under vacuum in an automated manner.

Each of processing chambers 24a-d may be configured to perform one or more process steps in the fabrication of a semiconductor structure, and any number of processing chambers and combinations of processing chambers may be used on multi-chamber processing system 10. For example, any of the processing chambers may be configured to perform a number of substrate processing operations including any number of deposition processes including cyclical layer deposition, atomic layer deposition, chemical vapor deposition, physical vapor deposition, as well as other operations including etch, pre-clean, pre-treatment, post-treatment, anneal, plasma processing, degas, orientation, and other substrate processes. Some specific processes that may be performed in any of the chambers or in any combination of chambers may be metal deposition, surface cleaning and preparation, thermal annealing such as rapid thermal processing, and plasma processing. Any other processes may similarly be performed in specific chambers incorporated into multi-chamber processing system 10, including any process described below, as would be readily appreciated by the skilled artisan.

FIG. 2 illustrates a schematic cross-sectional view of an exemplary processing chamber 100 suitable for patterning a material layer disposed on a substrate 302 in the processing chamber 100. The exemplary processing chamber 100 is suitable for performing a patterning process, although it is to be understood that aspects of the present technology may be performed in any number of chambers, and substrate supports according to the present technology may be included in etching chambers, deposition chambers, treatment chambers, or any other processing chamber. The plasma processing chamber 100 may include a chamber body 105 defining a chamber volume 101 in which a substrate may be processed. The chamber body 105 may have sidewalls 112 and a bottom 118 which are coupled with ground 126. The sidewalls 112 may have a liner 115 to protect the sidewalls 112 and extend the time between maintenance cycles of the plasma processing chamber 100. The dimensions of the chamber body 105 and related components of the plasma processing chamber 100 are not limited and generally may be proportionally larger than the size of the substrate 302 to be processed therein. Examples of substrate sizes include 200 mm diameter, 250 mm diameter, 300 mm diameter and 450 mm diameter, among others, such as display or solar cell substrates as well.

The chamber body 105 may support a chamber lid assembly 110 to enclose the chamber volume 101. The chamber body 105 may be fabricated from aluminum or other suitable materials. A substrate access port 113 may be formed through the sidewall 112 of the chamber body 105, facilitating the transfer of the substrate 302 into and out of the plasma processing chamber 100. The access port 113 may be coupled with a transfer chamber and/or other chambers of a substrate processing system as previously described. A pumping port 145 may be formed through the sidewall 112 of the chamber body 105 and connected to the chamber volume 101. A pumping device may be coupled through the pumping port 145 to the chamber volume 101 to evacuate and control the pressure within the processing volume. The pumping device may include one or more pumps and throttle valves.

A gas panel 160 may be coupled by a gas line 167 with the chamber body 105 to supply process gases into the chamber volume 101. The gas panel 160 may include one or more process gas sources 161, 162, 163, 164 and may additionally include inert gases, non-reactive gases, and reactive gases, as may be utilized for any number of processes. Examples of process gases that may be provided by the gas panel 160 include, but are not limited to, hydrocarbon containing gas including methane, sulfur hexafluoride, silicon chloride, carbon tetrafluoride, hydrogen bromide, hydrocarbon containing gas, argon gas, chlorine, nitrogen, helium, or oxygen gas, as well as any number of additional materials. Additionally, process gasses may include nitrogen, chlorine, fluorine, oxygen, and hydrogen containing gases such as H₂, NH₃, H₂O, H₂O₂, NF₃, HF, F₂, CF₄, CHF₃, C₂F₆, C₂F₄, C₃F₆, C₄F₆, C₄F₈, BrF₃, ClF₃, SF₆, CH₃F, CH₂F₂, BCl₃, PF₃, PH₃, COS, and SO₂, among any number of additional precursors.

Valves 166 may control the flow of the process gases from the sources 161, 162, 163, 164 from the gas panel 160 and may be managed by a controller 165. The flow of the gases supplied to the chamber body 105 from the gas panel 160 may include combinations of the gases form one or more sources. The lid assembly 110 may include a nozzle 114. The nozzle 114 may be one or more ports for introducing the process gases from the sources 161, 162, 164, 163 of the gas panel 160 into the chamber volume 101. After the process gases are introduced into the plasma processing chamber 100, the gases may be energized to form plasma. An antenna 148, such as one or more inductor coils, may be provided adjacent to the plasma processing chamber 100. An antenna power supply 142 may power the antenna 148 through a match circuit 141 to inductively couple energy, such as RF energy, to the process gas to maintain a plasma formed from the process gas in the chamber volume 101 of the plasma processing chamber 100. Alternatively, or in addition to the antenna power supply 142, process electrodes below the substrate 302 and/or above the substrate 302 may be used to capacitively couple RF power to the process gases to maintain the plasma within the chamber volume 101. The operation of the power supply 142 may be controlled by a controller, such as controller 165, that also controls the operation of other components in the plasma processing chamber 100.

A substrate support pedestal 135 may be disposed in the chamber volume 101 to support the substrate 302 during processing. The substrate support pedestal 135 may include an electrostatic chuck (“ESC”) 122 for holding the substrate 302 during processing. The electrostatic chuck 122 may use the electrostatic attraction to hold the substrate 302 to the substrate support pedestal 135. The ESC 122 may be powered by an RF power supply 125 integrated with a match circuit 124. The ESC 122 may include an electrode 121 embedded within a dielectric body. The electrode 121 may be coupled with the RF power supply 125 and may provide a bias which attracts plasma ions, formed by the process gases in the chamber volume 101, to the ESC 122 and substrate 302 seated on the pedestal. The RF power supply 125 may cycle on and off, or pulse, during processing of the substrate 302. The ESC 122 may have an isolator 128 for the purpose of making the sidewall of the ESC 122 less attractive to the plasma to prolong the maintenance life cycle of the ESC 122. Additionally, the substrate support pedestal 135 may have a cathode liner 136 to protect the sidewalls of the substrate support pedestal 135 from the plasma gases and to extend the time between maintenance of the plasma processing chamber 100.

Electrode 121 may be coupled with a power source 150. The power source 150 may provide a chucking voltage of about 500 volts to about 15,000 volts to the electrode 121. The power source 150 may also include a system controller for controlling the operation of the electrode 121 by directing a DC current to the electrode 121 for chucking and de-chucking the substrate 302. For example, similar to the RF power supply 125, power supply 150 may provide a bias which attracts plasma ions, formed by the process gases in the chamber volume 101, to the ESC 122 and substrate 302 seated on the pedestal. The power supply 150 may cycle on and off, or pulse, during processing of the substrate 302. In embodiments, the power supply 150 may supply RF power, DC current or voltage for chucking and/or bias, or a combination thereof. In additional embodiments, multiple power supplies may be configured to supply RF power and DC current or voltage for chucking and/or bias. The ESC 122 may include heaters disposed within the pedestal and connected to a power source for heating the substrate, while a cooling base 129 supporting the ESC 122 may include conduits for circulating a heat transfer fluid to maintain a temperature of the ESC 122 and substrate 302 disposed thereon. The ESC 122 may be configured to perform in the temperature range required by the thermal budget of the device being fabricated on the substrate 302. For example, the ESC 122 may be configured to maintain the substrate 302 at a temperature of about −150° C. or lower to about 500° C. or higher depending on the process being performed.

The cooling base 129 may be provided to assist in controlling the temperature of the substrate 302. To mitigate process drift and time, the temperature of the substrate 302 may be maintained substantially constant by the cooling base 129 throughout the time the substrate 302 is in the cleaning chamber. In some embodiments, the temperature of the substrate 302 may be maintained throughout subsequent cleaning processes at temperatures between about −150° C. and about 500° C., although any temperatures may be utilized. A cover ring 130 may be disposed on the ESC 122 and along the periphery of the substrate support pedestal 135. The cover ring 130 may be configured to confine etching gases to a desired portion of the exposed top surface of the substrate 302, while shielding the top surface of the substrate support pedestal 135 from the plasma environment inside the plasma processing chamber 100. Lift pins may be selectively translated through the substrate support pedestal 135 to lift the substrate 302 above the substrate support pedestal 135 to facilitate access to the substrate 302 by a transfer robot or other suitable transfer mechanism as previously described.

The controller 165 may be utilized to control the process sequence, regulating the gas flows from the gas panel 160 into the plasma processing chamber 100, and other process parameters. Software routines, when executed by the CPU, transform the CPU into a specific purpose computer such as a controller, which may control the plasma processing chamber 100 such that the processes are performed in accordance with the present disclosure. The software routines may also be stored and/or executed by a second controller that may be associated with the plasma processing chamber 100.

The chamber discussed previously may be used in performing exemplary methods, including etching methods, although any number of chambers may be configured to perform one or more aspects used in embodiments of the present technology. Turning to FIG. 3, exemplary operations in a method 300 according to embodiments of the present technology are shown. Method 300 may include one or more operations prior to the initiation of the method, including front end processing, deposition, etching, polishing, cleaning, or any other operations that may be performed prior to the described operations. The methods may include a number of optional operations, which may or may not be specifically associated with some embodiments of methods, according to embodiments of the present technology. For example, many of the operations are described in order to provide a broader scope of the processes performed, but are not critical to the technology, or may be performed by alternative methodology as will be discussed further below. Method 300 may describe operations shown schematically in FIGS. 4A-4D, the illustrations of which will be described in conjunction with the operations of method 300. It is to be understood that the figures illustrate only partial schematic views, and a substrate may contain any number of additional materials and features having a variety of characteristics and aspects as illustrated in the figures.

Method 300 may or may not involve optional operations to develop the semiconductor structure to a particular fabrication operation. It is to be understood that method 300 may be performed on any number of semiconductor structures 400 or substrates 405, as illustrated in FIG. 4A, including exemplary structures on which one or more silicon-containing material etching operations may be performed. As illustrated in FIG. 4A, substrate 405 may include one or more stacked layers of material overlying the substrate 405, which may be silicon, silicon germanium, or other substrate materials. While any number of layers of material are contemplated, the exemplary structure 400 shown in FIG. 4A may include a layer of a first silicon-containing material 410 and a layer of a second silicon-containing material 415. However, it is contemplated that the structure 400 may include any number of silicon-containing materials. For example, the structure 400 may include repeated alternating layers of multiple silicon-containing materials. As illustrated in FIG. 4A, a metal-containing material 420, such as a metal-and-nitrogen-containing material (e.g., a titanium-and-nitrogen-containing material), may optionally overly the uppermost silicon-containing material, such as the layer of the second silicon-containing material 415. However, it is also contemplated that some embodiments may not include the metal-containing material 420. Further, a mask material 425, which may be patterned to form an aperture 430 extending through a thickness of the mask material 425, may overly the metal-containing material 420. The aperture 430 may expose the underlying layers and may allow for one or more holes or trenches to be formed through the underlying layers. Although only a single aperture 430 is illustrated, it is to be understood that exemplary structure 400 may include any number of apertures across the substrate 405. Any of the processing to form structure 400 may be performed in chambers or system tools as previously described, or may be performed in different chambers on the same system tool, which may include the chamber in which the operations of method 300 are performed.

Method 300 may be performed to etch or otherwise remove portions of the layers of material underlying mask material 425 and exposed through aperture 430. In embodiments, as illustrated in FIG. 4B, method 300 may include removing a portion of the metal-containing material 420 to form a hole or trench 435 through the metal-containing material 420. The formation of the hole or trench 435 through the metal-containing material 420 may expose the underlying material, such as the layer of the second silicon-containing material 415.

At operation 305, method 300 may include providing an etchant precursor to the processing region of the semiconductor processing chamber. Structure 400 and substrate 405 may be disposed within the processing region. Method 300 may include providing a carbon-containing precursor to the processing region with the etchant precursor. The carbon-containing precursor may be provided to passivate sidewalls of the materials not to be etched (or to passivate sidewalls of the materials being etched during etching). In embodiments, the etchant precursor may also include constituents, such as sulfur, to serve as passivation material. Method 300 may include forming plasma effluents of the etchant precursor at operation 310. In embodiments, the plasma effluents of the etchant precursor may be formed using inductively coupled plasma (ICP). As such, operation 310 may include forming inductively coupled plasma effluents of the etchant precursor. At operation 315, method 300 may include contacting the substrate 405 with the plasma effluents of the etchant precursor. The contacting may etch a portion of the exposed material, such as the layer of the second silicon-containing material 415. In embodiments, method 300 may include applying a bias power while contacting the substrate 405 with the plasma effluents of the etchant precursor.

At operation 320, method 300 may include halting a flow of the etchant precursor. The flow of the etchant precursor may be halted to stop etching or to change the etchant precursor to etch another material, such as the layer of the first silicon-containing material 410. For example, the layer of the second silicon-containing material 415 may be etched with a first etchant precursor, and method 300 may include halting a flow of the first etchant precursor prior to providing the second etchant precursor at operation 320. The second etchant precursor may then be provided to etch the layer of the first silicon-containing material 410. For example, operations 305-315 may be repeated for a second cycle, optionally with a different etchant precursor, to etch or remove a different material, such as the layer of the first silicon-containing material 410.

In one exemplary embodiment, and as illustrated in FIG. 4C, operation 315 of a first cycle of method 300 may be continued for a period of time to etch hole or trench 435 through the layer of the second silicon-containing material 415. After the layer of the second silicon-containing material 415 has been etched to expose the layer of the first silicon-containing material 410, a flow of the etchant precursor, such as a first etchant precursor may be halted, such as at operation 320 of the first cycle of method 300. Operation 305 of a second cycle of method 300 may then be performed to provide a different etchant precursor, such as a second etchant precursor. Operation 310 of the second cycle of method 300 may then be performed to form plasma effluents of the second etchant precursor. In embodiments, the plasma effluents of the second etchant precursor may be formed using ICP. As such, operation 310 of the second cycle of method 300 may include forming inductively coupled plasma effluents of the second etchant precursor. The second cycle of method 300 may include contacting the substrate 405 with the plasma effluents of the second etchant precursor at operation 315 for a second period of time. The contacting may etch a portion of the layer of the second silicon-containing material. In embodiments, the second period of time may be sufficient to etch hole or trench 435 through the layer of the first silicon-containing material 410, such as to expose an underlying material. As illustrated in FIG. 4D, the second period of time may be sufficient to etch hole or trench 435 through the layer of the first silicon-containing material 410 to expose the substrate 405. At operation 320 of the second cycle of method 300, a flow of the second etchant precursor may be halted.

In one exemplary embodiment, a third cycle of method 300 may be performed to etch another material, such as substrate 405 as illustrated in FIG. 4E. For example, after halting the flow of the second etchant precursor at operation 320 of the second cycle of method 300, operation 305 of a third cycle of method 300 may include providing a third etchant precursor to the processing region. Operation 310 of the third cycle of method 300 may include forming plasma effluents of the third etchant precursor. In embodiments, the plasma effluents of the third etchant precursor may be formed using ICP. As such, operation 310 of the third cycle of method 300 may include forming inductively coupled plasma effluents of the third etchant precursor. The third cycle of method 300 may include contacting the substrate 405 with the plasma effluents of the third etchant precursor at operation 315 for a third period of time. The contacting may etch a portion of the substrate 405. In embodiments, s illustrated in FIG. 4E, the third period of time may be sufficient to etch hole or trench 435 into the substrate 405. At operation 320 of the third cycle of method 300, a flow of the third etchant precursor may be halted.

It is contemplated that the operations of method 300 may be repeated for as many cycles as necessary or desired to etch through any number of layers of material in the structure. While structure 400 only depicts three layers of silicon-containing materials, a structure may include any number of layers of silicon-containing materials, thus requiring additional cycles of method 300.

Etchant precursors provided at operation 305 of any cycle of method 300 may be or include halogen-containing precursors. Halogen-containing precursors provided at operation 305 may include, for example, fluorine-containing precursors, chlorine-containing precursor, bromine-containing precursors, or any other halogen-containing precursors able to etch silicon-containing materials. Exemplary fluorine-containing precursors provided at operation 305 may include hydrogen fluoride (HF), nitrogen trifluoride (NF₃), diatomic fluorine (F₂), bromine trifluoride (BrF₃), a fluorocarbon (CHₓF_{y}), such as fluoromethane (CH₃F), fluoroform (CHF₃), or difluoromethane (CH₂F₂), hexafluorobutadiene (C₄F₆), chlorine trifluoride (ClF₃), sulfur hexafluoride (SF₆), xenon difluoride (XeF₂), carbon tetrafluoride (CF₄), or any organofluoride, or any other fluorine-containing precursor used or useful in semiconductor processing.

In embodiments, different etchant precursors may be used depending on the silicon-containing material to be etched. For example, HF, NF₃, CH₃F, CF₄, CHF₃, and C₄F₆ may be preferable for etching silicon-and-oxygen-containing materials. SF₆, C₄F₆, CH₂F₂, CH₃F, CHF₃, and CF₄ may be preferable for etching silicon-and-nitrogen-containing materials as well as silicon material. As such, the etchant precursor provided at each operation 305 of various cycles of method 300 may differ. However, it is contemplated that the same or similar etchant precursors may be used during individual cycles of method 300.

As previously discussed, embodiments may include providing a carbon-containing precursor with the etchant precursor. Exemplary carbon-containing precursors provided with the etchant precursor at operation 305 may include CH₃F, CHF₃, CH₂F₂, C₄F₆, ClF₃, CF₄, CH₄, or any other carbon-containing precursor used or useful in semiconductor processing.

The carbon-containing precursor may be provided at a reduced flow compared to a flow of the etchant precursor. The carbon-containing precursor may passivate a sidewall of the portion of the layer of the first silicon-containing material, a sidewall of the portion of the layer of the second silicon-containing material, and/or the substrate, depending on which region of the structure 400 is being etched. In embodiments, a flow rate of the etchant precursor may be greater than or about 100 sccm, and may be greater than or about 150 sccm, greater than 200 sccm, greater than or about 250 sccm, greater than or about 300 sccm, greater than or about 400 sccm, greater than or about 500 sccm, greater than or about 750 sccm, greater than or about 1,000 sccm, greater than or about 1,500 sccm, greater than or about 2,000 sccm, or more. A flow rate of the carbon-containing precursor may be less than or about 500 sccm, and may be less than or about 400 sccm, less than or about 300 sccm, less than or about 250 sccm, less than or about 200 sccm, less than or about 150 sccm, less than or about 100 sccm, less than or about 75 sccm, less than or about 50 sccm, less than or about 25 sccm, less than or about 20 sccm, less than or about 15 sccm, less than or about 10 sccm, or less.

The etchant precursor and the carbon-containing precursor, if present, may also be provided with any number of additional precursors or carrier gases including nitrogen, argon, helium, or any number of additional materials, although in some embodiments the precursors may be limited to control side reactions or other aspects that may impact the etching. A hydrogen-containing precursor, such as diatomic hydrogen (H₂) or ammonia (NH₃), may also be provided with the etchant precursor and the carbon-containing precursor, if present.

The plasma power used to form plasma effluents of the etchant and, if present, the carbon-containing precursor may be a relatively high plasma power. The relatively low plasma power may allow for formation of HF molecules. At higher plasma powers, increased etchant radicals may form and etch rates may increase, which may increase throughput. Accordingly, the plasma effluents of the etchant precursor and, if present, the carbon-containing precursor may be formed at greater than or about 1,000 W, and may be formed at greater than or about 1,500 W, greater than or about 2,000 W, greater than or about 2,500 W, greater than or about 3,000 W, greater than or about 3,500 W, greater than or about 4,000 W, greater than or about 4,500 W, greater than or about 5,000 W, or more. However, very high plasma powers may result in a less controlled etch. Therefore, the plasma effluents of the etchant precursor and, if present, the carbon-containing precursor may be formed at less than or about 6,500 W, and may be formed at less than or about 6,000 W, less than or about 5,500 W, or less.

While forming the plasma effluents of the etchant precursor and, if present, the carbon-containing precursor at operation 310 and/or while contacting the substrate with the etchant precursor and, if present, the carbon-containing precursor at operation 315, a bias power may be applied. The bias power, which may be a 2 MHz frequency or a voltage applied to the pedestal or substrate support, may increase directionality of the plasma effluents of the etchant precursor and, if present, the carbon-containing precursor. The increased directionality may draw the plasma effluents of the etchant precursor and, if present, the carbon-containing precursor to the substrate 405. Accordingly, the plasma effluents of the etchant precursor and, if present, the carbon-containing precursor may bombard the substrate 405 and increase removal. In embodiments, the bias power applied may be greater than or about 1,000 W, and may be greater than or about 1,500 W, greater than or about 2,000 W, greater than or about 2,500 W, greater than or about 3,000 W, greater than or about 3,500 W, greater than or about 4,000 W, greater than or about 4,500 W, greater than or about 5,000 W, or more. However, at higher bias powers, the bombardment may increase and materials on substrate 405 or in structure 400 may begin to sputter. Accordingly, the bias power applied may be less than or about 6,500 W, and may be less than or about 6,000 W, less than or about 5,500 W, or less.

While contacting the substrate with the etchant precursor and during the resultant etching, one or more etch byproducts may form. At the reduced chamber operating temperatures, the etch byproducts may serve as passivation material. Conversely, in conventional technologies at higher temperatures, the etch byproducts may be volatile materials. The etch byproducts of the present technology, which may depend on the etchant precursor and/or material being etched, may include, but are not limited to, ammonium fluorosilicate ((NH₄)₂SiF₆)) and silicon oxyfluoride (SiOₓF_{y}). Accordingly, in embodiments, additional passivation precursors may not be needed to passivate sidewalls of the material during the etching.

The portion of the material being etched, such as the portion layer of the first silicon-containing material 410, the portion of the layer of the second silicon-containing material 415, and/or a portion of the substrate 405, may be characterized by a critical dimension of greater than or about 50 nm, and may be characterized by a critical dimension of greater than or about 100 nm, greater than or about 125 nm, greater than or about 150 nm, greater than or about 175 nm, greater than or about 200 nm, or more.

While any thicknesses of materials being etched are contemplated, any or all of the materials may be characterized by a thickness of greater than or about 100 nm, and may be greater than or about 250 nm, greater than or about 500 nm, greater than or about 750 nm, greater than or about 1 μm, greater than or about 1.5 μm, greater than or about 2 μm, greater than or about 2.5 μm, greater than or about 3 μm, greater than or about 4 μm, greater than or about 5 μm, or more. The present technology may be characterized by an increased etch rate compared to conventional technologies, which may require multiple iterations of passivation deposition and etching. In embodiments, depending on the material being etched, such as the silicon-containing material being etched, an etch rate may be greater than or about 0.3 μm/minute, and may be greater than or about 0.4 μm/minute, greater than or about 0.5 μm/minute, greater than or about 0.6 μm/minute, greater than or about 0.7 μm/minute, greater than or about 0.8 μm/minute, greater than or about 0.9 μm/minute, greater than or about 1.0 μm/minute, greater than or about 1.2 μm/minute, greater than or about 1.4 μm/minute, greater than or about 1.6 μm/minute, greater than or about 1.7 μm/minute, greater than or about 2.0 μm/minute, greater than or about 2.5 μm/minute, greater than or about 3.0 μm/minute, or more. For example, the etch rate of silicon-and-oxygen-containing material may be between about 0.2 μm/minute and about 0.6 μm/minute, whereas the etch rate of silicon-containing material and/or silicon-and-nitrogen-containing material may be between about 2.0 μm/minute and about 3.0 μm/minute.

Process conditions may also impact the operations performed in method 300. Each of the operations and cycles of method 300 may be performed during a constant temperature in embodiments, while in some embodiments the temperature may be adjusted during different operations or different cycles of method 300. Temperatures may be maintained in any range, however, at lower temperatures, more etchant radicals may condense on a surface of the substrate 405, such as the material being etched, and ay increase the etch rate. Additionally, at lower temperatures, water (H₂O), a byproduct from the removal of silicon-containing material including oxygen, may condense on the substrate 405 and serve to accelerate the etch, such as the etch of silicon-and-oxygen-containing material or other silicon-containing materials. Accordingly, in some embodiments any or all operations of the method 300 may be performed at a cryogenic temperature such as a chamber operating temperature of less than or about −50° C., less than or about −60° C., less than or about −70° C., less than or about −80° C., less than or about −90° C., or less.

Each of the operations and cycles of method 300 may be performed during a constant pressure in embodiments, while in some embodiments the pressure may be adjusted during different operations or different cycles of method 300. Pressures may be maintained in any range, however, at lower pressures, a mean free path may increase and a higher concentration of etchant radicals at the substrate 405 may increase. The increased mean free path and concentration of etchant radicals may increase etch rates. Accordingly, in some embodiments, any or all operations of the method 300 may performed at a chamber operating pressure of less than or about 500 mTorr, and may be performed at a chamber operating pressure of less than or about 400 mTorr, less than or about 350 mTorr, less than or about 300 mTorr, less than or about 250 mTorr, less than or about 200 mTorr, less than or about 150 mTorr, less than or about 100 mTorr, less than or about 70 mTorr, less than or about 65 mTorr, less than or about 60 mTorr, less than or about 55 mTorr, less than or about 50 mTorr, less than or about 45 mTorr, less than or about 40 mTorr, less than or about 35 mTorr, less than or about 30 mTorr, or less. However, too low of a pressure may result in reduced generation of etchant radicals. As such, in some embodiments, any or all operations of the method 300 may performed at a chamber operating pressure of greater than or about 5 mTorr, and may be performed at a chamber operating pressure of greater than or about 10 mTorr, greater than or about 15 mTorr, greater than or about 20 mTorr, greater than or about 25 mTorr, greater than or about 30 mTorr, greater than or about 35 mTorr, greater than or about 40 mTorr, greater than or about 45 mTorr, greater than or about 50 mTorr, greater than or about 55 mTorr, greater than or about 60 mTorr, or more.

As previously discussed, the present technology may etch or remove multiple layers of material, such as substrate, first silicon-containing material 410, and second silicon-containing material 415. While multiple semiconductor processing chambers may be used, the present technology may also etch or remove all layers of material in a single processing region of a single semiconductor processing chamber. As such, the present technology may greatly reduce queue times necessitated by transferring substrates between multiple processing regions and, therefore, increase throughput.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology. Additionally, methods or processes may be described as sequential or in steps, but it is to be understood that the operations may be performed concurrently, or in different orders than listed.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a precursor” includes a plurality of such precursors, and reference to “the layer” includes reference to one or more layers and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

1. A semiconductor processing method comprising:
providing an etchant precursor to a processing region of a semiconductor processing chamber, wherein a substrate is disposed within the processing region, wherein the substrate comprises a layer of a silicon-containing material, wherein the silicon-containing material comprises a silicon-and-carbon-containing material, a silicon-carbon-and-nitrogen-containing material, a silicon-and-nitrogen-containing material, a silicon-and-oxygen-containing material, or silicon material;
forming plasma effluents of the etchant precursor;
contacting the substrate with the plasma effluents of the etchant precursor, wherein the contacting etches a portion of the layer of the silicon-containing material, and wherein the processing region is maintained at a cryogenic temperature while contacting the substrate with the plasma effluents of the etchant precursor.

2. The semiconductor processing method of claim 1, wherein the substrate further comprises a patterned mask material overlying the layer of the silicon-containing material.

3. The semiconductor processing method of claim 1, wherein:
the silicon-containing material comprises a silicon-and-nitrogen-containing material; and
the etchant precursor comprises hydrogen fluoride (HF), nitrogen trifluoride (NF₃), sulfur hexafluoride (SF₆), or a fluorocarbon (CHₓF_{y}).

4. The semiconductor processing method of claim 1, wherein:
the silicon-containing material comprises a silicon-and-oxygen-containing material; and
the etchant precursor comprises hydrogen fluoride (HF), nitrogen trifluoride (NF₃), or a fluorocarbon (CHₓF_{y}).

5. The semiconductor processing method of claim 1, further comprising:
providing a carbon-containing precursor to the processing region with the etchant 2 precursor.

6. The semiconductor processing method of claim 1, wherein the plasma effluents of the etchant precursor are an inductively coupled plasma (ICP).

7. The semiconductor processing method of claim 1, further comprising:
applying a bias power while contacting the substrate with the plasma effluents of the etchant precursor.

8. A semiconductor processing method comprising:
providing a first etchant precursor to a processing region of a semiconductor processing chamber, wherein a substrate is disposed within the processing region, wherein the substrate comprises a layer of a first silicon-containing material and a layer of a second silicon-containing material, wherein the first silicon-containing material and the second silicon-containing material comprise a silicon-and-carbon-containing material, a silicon-carbon-and-nitrogen-containing material, a silicon-and-nitrogen-containing material, a silicon-and-oxygen-containing material, or silicon material, and wherein the first silicon-containing material and the second silicon-containing material are different silicon-containing materials;
forming plasma effluents of the first etchant precursor;
contacting the substrate with the plasma effluents of the first etchant precursor at a cryogenic temperature, wherein the contacting etches a portion of the layer of the first silicon-containing material;
providing a second etchant precursor to the processing region;
forming plasma effluents of the second etchant precursor; and
contacting the substrate with the plasma effluents of the second etchant precursor at a cryogenic temperature, wherein the contacting etches a portion of the layer of the second silicon-containing material, and wherein the processing region is maintained at a cryogenic temperature.

9. The semiconductor processing method of claim 8, wherein the first etchant precursor and the second etchant precursor comprise hydrogen fluoride (HF), nitrogen trifluoride (NF₃), fluoromethane (CH₃F), carbon tetrafluoride (CF₄), fluoroform (CHF₃), difluoromethane (CH₂F₂), hexafluorobutadiene (C₄F₆), or sulfur hexafluoride (SF₆).

10. The semiconductor processing method of claim 8, further comprising:
halting a flow of the first etchant precursor prior to providing the second etchant precursor.

11. The semiconductor processing method of claim 8, further comprising:
providing a carbon-containing precursor with the first etchant precursor, the second etchant precursor, or both.

12. The semiconductor processing method of claim 8, further comprising:
passivating a sidewall of the portion of the layer of the first silicon-containing material, a sidewall of the portion of the layer of the second silicon-containing material, or both.

13. The semiconductor processing method of claim 8, wherein the portion of the layer of the first silicon-containing material, the portion of the layer of the second silicon-containing material, or both are characterized by a critical dimension of greater than or about 50 nm.

14. The semiconductor processing method of claim 8, wherein the layer of the first silicon-containing material and the layer of the second silicon-containing material are each characterized by a thickness of greater than or about 100 nm.

15. The semiconductor processing method of claim 8, wherein the substrate further comprises:
a layer of a metal-and-nitrogen-containing material on the layer of the first silicon-containing material; and
a patterned mask material on the layer of the metal-and-nitrogen-containing material.

16. The semiconductor processing method of claim 12, wherein:
the layer of the first silicon-containing material comprises silicon-and-oxygen-containing material; and
the layer of the second silicon-containing material comprises silicon material.

17. The semiconductor processing method of claim 12, the processing region is maintained at a pressure of less than or about 500 mTorr.

18. A semiconductor processing method comprising:
providing a first etchant precursor to a processing region of a semiconductor processing chamber, wherein a substrate is disposed within the processing region, wherein the substrate comprises a layer of a first silicon-containing material, a layer of a second silicon-containing material, and a layer of a third silicon-containing material, wherein the first silicon-containing material, the second silicon-containing material, and the second silicon-containing material comprise a silicon-and-carbon-containing material, a silicon-carbon-and-nitrogen-containing material, a silicon-and-nitrogen-containing material, a silicon-and-oxygen-containing material, or silicon material, and wherein the first silicon-containing material, the second silicon-containing material, and the second silicon-containing material are different silicon-containing materials;
forming plasma effluents of the first etchant precursor;
contacting the substrate with the plasma effluents of the first etchant precursor at a cryogenic temperature, wherein the contacting etches a portion of the layer of the first silicon-containing material;
providing a second etchant precursor to the processing region;
forming plasma effluents of the second etchant precursor;
contacting the substrate with the plasma effluents of the second etchant precursor at a cryogenic temperature, wherein the contacting etches a portion of the layer of the second silicon-containing material;
providing a third etchant precursor to the processing region;
forming plasma effluents of the third etchant precursor; and
contacting the substrate with the plasma effluents of the third etchant precursor at a cryogenic temperature, wherein the contacting etches a portion of the layer of the third silicon-containing material.

19. The semiconductor processing method of claim 18, further comprising:
applying a bias power contacting the substrate with the plasma effluents of the first etchant precursor, the plasma effluents of the second etchant precursor, and the plasma effluents of the third etchant precursor.

20. The semiconductor processing method of claim 18, wherein contacting the substrate with the plasma effluents of the first etchant precursor, the plasma effluents of the second etchant precursor, and the plasma effluents of the third etchant precursor are performed in the same semiconductor processing chamber.
